(19) United States
(12) Patent Application Publication
(10) Pub. No.: US 2010/0227476 A1
(43) Pub. Date: Sep. 9, 2010

(54) ATOMIC LAYER DEPOSITION PROCESSES

(76) Inventor: John D. Peck, West Seneca, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 12/714,579

(22) Filed: Mar. 1, 2010

Related U.S. Application Data
(60) Provisional application No. 61/157,293, filed on Mar. 4, 2009.

(51) Int. Cl. H01L 21/3205

(52) U.S. Cl. 438/680; 257/E21.295

(57) ABSTRACT

This invention relates to method of forming a thin film on a substrate in a reaction chamber by an atomic layer deposition process comprising a plurality of individual cycles. The plurality of individual cycles comprise at least two groupings of individual cycles. The individual cycles comprise (i) introducing a gaseous metal containing precursor into the reaction chamber and exposing the substrate to the gaseous metal containing precursor, wherein at least a portion of the metal containing precursor is chemisorbed onto the surface of the substrate to form a monolayer thereon, (ii) stopping introduction of the metal containing precursor and purging the volume of the reaction chamber; (iii) introducing a gaseous oxygen source compound into the reaction chamber and exposing the monolayer to the gaseous oxygen source compound, wherein at least a portion of the oxygen source compound chemically reacts with the monolayer; and (iv) stopping introduction of the oxygen source compound and purging the volume of the reaction chamber. The method involves repeating the individual cycles until a thin film of desired thickness is obtained. The method also involves carrying out at least two groupings of individual cycles at different process conditions. The methods are useful for producing a thin film on a semiconductor substrate, particularly metal containing thin films for electrode applications in microelectronics.

### RELATED APPLICATIONS

This application claims priority from provisional U.S. patent application Ser. No. 61/157,293, filed Mar. 4, 2009, which is incorporated herein by reference.

### FIELD OF THE INVENTION

This invention relates to atomic layer deposition processes for producing a metal containing thin film on a semiconductor substrate, particularly metal containing thin films for electrode applications in microelectronics.

### BACKGROUND OF THE INVENTION

Atomic layer deposition (ALD) methods offer many advantages over the traditional deposition methods. ALD relies on self-limiting surface reactions in order to provide accurate thickness control, excellent conformality, and uniformity over large areas. As the microscopic features on a chip grow increasingly narrow and deep, these unique features make ALD one of the most promising deposition methods in the manufacturing of the future circuits. The feature that makes ALD a unique deposition method compared to other methods is that it deposits atoms or molecules on a wafer a single layer at a time.

ALD accomplishes deposition by introducing gaseous precursors alternately onto a workpiece such as, for example, semiconductor substrate or wafer. Typically, ALD processes involve a sequence of steps. The steps include 1) adsorption of a precursor on the surface of a substrate, 2) purging off excess precursor molecules in gas phase, 3) introducing a reactant to react with the precursor on the substrate surface, and 4) purging off excess reactant. The surface reactions are self-controlled and produce no detrimental gas phase reactions, thereby enabling accurate control of film thickness by counting the number of deposition cycles. Under properly adjusted processing conditions, i.e., deposition temperature, reactant dose, length of precursor and purge pulses, a chemisorbed monolayer of a precursor is left on the surface of the workpiece after a complete cycle.

Typically, ALD processes are operated under fixed operating conditions. For example, the oxygen concentration during the cycles of an ALD process does not vary. This can cause problems for the deposition of certain metal films. For example, fixed ALD operating conditions involving ruthenium films yield either thin (less than 20 nm) ruthenium films with high nucleation density that are susceptible to blistering, or thick (greater than 20 nm) ruthenium films with low nucleation density that are devoid of blistering. Increasing nucleation density beyond a certain value results in film blistering during ALD using certain ruthenium compounds and oxygen. Blistering occurs when external forces (e.g., film stress) overcome adhesion.

Atomic layer deposition (ALD) is considered a superior technology for depositing thin films. However, one challenge for ALD technology is the ability to deposit high nucleation density metal, e.g., ruthenium, films less than 20 nm thick, yet not result in blistering as the coalesced film gets thicker than 20 nm. If a film blisters, it generally becomes unusable.

Therefore, a need continues to exist for developing improved ALD processes. It would be desirable in the art to develop improved ALD methods that can provide thin, high nucleation density metal films, e.g., ruthenium films less than 20 nm thick, that do not exhibit blistering even as the coalesced film gets thicker than 20 nm.

### SUMMARY OF THE INVENTION

This invention relates in part to a method of forming a thin film on a substrate in a reaction chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber, (iii) introducing a gaseous oxygen source compound into said reaction chamber and exposing said monolayer to said gaseous oxygen source compound, wherein at least a portion of said oxygen source compound chemically reacts with said monolayer, and (iv) stopping introduction of said oxygen source compound and purging the volume of said reaction chamber; repeating said individual cycles until a thin film of desired thickness is obtained; and carrying out at least two groupings of individual cycles at different process conditions.

This invention also relates in part to a method for processing a substrate in a processing chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber, (iii) introducing a gaseous oxygen source compound into said reaction chamber and exposing said monolayer to said gaseous oxygen source compound, wherein at least a portion of said oxygen source compound chemically reacts with said monolayer, and (iv) stopping introduction of said oxygen source compound and purging the volume of said reaction chamber; repeating said individual cycles until a thin film of desired thickness is obtained; and carrying out at least two groupings of individual cycles at different process conditions.

This invention further relates in part to a method for forming a metal containing material on a substrate in a reaction chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber containing a substrate and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber; (iii) introducing a gaseous oxygen source compound into said reaction chamber and exposing said monolayer to said gaseous oxygen source compound, wherein at least a portion of said oxygen source compound chemically reacts with said monolayer; and (iv) stopping introduction of said oxygen source compound and purging the volume of said reaction chamber; repeating said individual cycles until a thin film of desired thickness is obtained; and carrying out at least two groupings of individual cycles at different process conditions. The metal containing material on the substrate can thereafter be metallized with copper or integrated with a ferroelectric thin film (e.g., SrTiO₃).

This invention yet further relates in part to a method of fabricating a microelectronic device structure in a reaction chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber containing a substrate and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber, (iii) introducing a gaseous oxygen source compound into said reaction chamber and exposing said monolayer to said gaseous oxygen source compound, wherein at least a portion of said oxygen source compound chemically reacts with said monolayer, and (iv) stopping introduction of said oxygen source compound and purging the volume of said reaction chamber; repeating said individual cycles until a thin film of desired thickness is obtained; and carrying out at least two groupings of individual cycles at different process conditions. The method further comprises incorporating the thin film into a semiconductor integration scheme.

The invention has several advantages. For example, the ALD methods of this invention can provide thin, high nucleation density metal films, e.g., ruthenium films less than 20 nm thick, that do not exhibit blistering even as the coalesced film gets thicker than 20 nm. By varying process conditions (e.g., oxygen concentration) after establishing the nucleation layer, blistering is avoided. The ALD methods of this invention can enable the use of ruthenium films as an electrode in semiconductor applications. For conventional ALD methods to generate films having no blistering, a separate annealing step would be required which would increase process time and cost. In addition, the known advantages of ALD (accurate and simple control of film thickness, excellent step coverage, i.e. conformality, and large area uniformity) can be obtained from deposition of thin metal films in accordance with this invention.

### DETAILED DESCRIPTION OF THE INVENTION

This invention relates generally to methods of producing thin films by ALD processes. According to methods of this invention, a substrate with a surface is placed in a reaction chamber, the substrate is heated up to suitable deposition temperature at lowered pressure, a metal containing precursor reactant is conducted in the form of gas phase pulses into the reaction chamber and contacted with the surface of the substrate to bind or adsorb no more than about one monolayer of the metal containing precursor reactant onto the surface, excess of the metal containing precursor reactant is purged out of the reaction chamber in vaporous or gas form, a gaseous oxygen source reactant is pulsed onto the substrate to provide a surface reaction between the oxygen source reactant and the metal containing precursor reactant bound to the surface, excess of the oxygen source reactant and gaseous byproducts of the surface reactions are purged out of the reaction chamber, and the steps of pulsing and purging (i.e., individual cycles) are repeated in the indicated order until the desired thickness of the depositing thin film is reached. The reaction chamber may also be purged prior to the first pulsing of the metal containing precursor into the reaction chamber. The ALD process comprises a plurality of individual cycles. The individual cycles can be conducted in groupings and the process conditions of the groupings can be different.

The ALD method is based on controlled surface reactions of the metal containing precursor chemicals. Gas phase reactions are avoided by feeding reactants alternately into the reaction chamber. Vapour phase reactants are separated from each other in the reaction chamber by removing excess reactants and/or reactant byproducts from the reaction chamber, such as with an evacuation step and/or with an inactive gas pulse (e.g., nitrogen or argon).

In an embodiment, this invention relates to a method of forming a thin film on a substrate in a reaction chamber by an ALD process comprising a plurality of individual cycles. The plurality of individual cycles comprise at least two groupings of individual cycles. The individual cycles comprise (i) introducing a gaseous metal containing precursor into the reaction chamber and exposing the substrate to the gaseous metal containing precursor, wherein at least a portion of the metal containing precursor is chemisorbed onto the surface of the substrate to form a monolayer thereon, (ii) stopping introduction of the metal containing precursor and purging the volume of the reaction chamber, (iii) introducing a gaseous oxygen source compound into the reaction chamber and exposing the monolayer to the gaseous oxygen source compound, wherein at least a portion of the oxygen source compound chemically reacts with the monolayer, and (iv) stopping introduction of the oxygen source compound and purging the volume of the reaction chamber. The method involves repeating the individual cycles until a thin film of desired thickness is obtained. The method also involves carrying out at least two groupings of individual cycles at different process conditions.

The ALD methods of this invention are comprised of a plurality of individual cycles. The plurality of individual cycles include at least 2, and can include 3 or more, groupings of individual cycles. The groupings of individual cycles can include a wide number of individual cycles, for example, 10 or less to 100 or more. The individual cycles are repeated until a thin film of desired thickness is obtained.

In an embodiment, the desired number of cycles for the metal film deposition is a number of cycles to form a metal layer across the substrate providing a thickness of a few angstroms. In an embodiment, performing about four to ten individual cycles provides a few angstroms thickness. Forming the metal layer on the substrate prior to forming a metal oxide prevents the formation of non-conductive oxides on the substrate surface during subsequent ALD formation. As the metal oxide is being formed by ALD, oxygen that diffuses towards the substrate reacts with the metal layer. In an embodiment, the metal layer substantially becomes metal oxide.

The groupings of individual cycles employed in the ALD methods are preferably carried out at different process conditions. Alternating process conditions between the groupings of individual cycles, for example, alternating oxygen concentration (low O₂/high O₂/low O₂/high O₂ . . . ) between different groupings, can impart desired film properties. Other process parameters such as temperature and pressure can also be varied between the groupings of individual cycles to impart desired film properties, e.g., eliminating blistering of films. It has been found that by varying ALD process conditions, such a oxygen concentration, that ruthenium containing films can be produced that are blister-free.

In ALD methods, the individual cycles make the metal film growth self-limiting. This self-limiting growth results in large area uniformity and conformality, which has important applications for such cases as planar substrates, deep trenches, and in the processing of porous silicon and high surface area silica and alumina powders. Thus, ALD provides for controlling layer thickness in a straightforward manner by controlling the number of growth cycles.

ALD processes are advantageous in that they provide for improved control of atomic-level thickness and uniformity to the deposited layer by providing a plurality of self-limiting deposition cycles. The self-limiting nature of ALD provides a method of depositing a film on any suitable reactive surface including, for example, surfaces with irregular topographies.

A typical ALD process includes exposing a substrate to a metal containing precursor to accomplish chemisorption of the metal onto the substrate. Typically in chemisorption, one or more of the ligands of the metal containing precursor is displaced by reactive groups on the substrate surface. Theoretically, the chemisorption forms a monolayer that is uniformly one atom or molecule thick on the entire exposed initial substrate, the monolayer being composed of the metal containing precursor, less any displaced ligands. In other words, a saturated monolayer is substantially formed on the substrate surface. Practically, chemisorption may not occur on all portions of the substrate. Nevertheless, such a partial monolayer is still understood to be a monolayer in the context of this invention. In many applications, merely a substantially saturated monolayer may be suitable. A substantially saturated monolayer is one that will still yield a deposited layer exhibiting the quality and/or properties desired for such layer.

Practically, chemisorption might not occur on all portions of the deposition surface (e.g., previously deposited ALD material). Nevertheless, such imperfect monolayer is still considered a monolayer in the context of this invention. In many applications, merely a substantially saturated monolayer may be suitable. In one aspect, a substantially saturated monolayer is one that will still yield a deposited monolayer or less of material exhibiting the desired quality and/or properties. In another aspect, a substantially saturated monolayer is one that is self-limited to further reaction with precursor. For purposes of this invention, the term “monolayer” includes not only a saturated monolayer, but also a less than saturated monolayer, e.g., a partial monolayer, and a greater than saturated monolayer, e.g., a multi-monolayer. In the practice of this invention, the monolayers preferably exhibit large area uniformity and conformality.

The metal containing precursor (e.g., substantially all non-chemisorbed molecules of the metal containing precursor) as well as displaced ligands are purged from over the substrate and a gaseous oxygen source compound is provided to react with the monolayer of the metal containing precursor. Unreacted oxygen source compound, as well as displaced ligands and other byproducts of the reaction are then purged and the steps are repeated with exposure of the monolayer to vaporized metal containing precursor. That is, the oxygen source compound can cleave some portion of the chemisorbed metal containing precursor, altering such monolayer without forming another monolayer thereon, but leaving reactive sites available for formation of subsequent monolayers. In other ALD processes, a third reactant or more may be successively chemisorbed (or reacted) and purged just as described for the precursor and oxygen source compound, with the understanding that each introduced reactant reacts with the monolayer produced immediately prior to its introduction.

The byproducts in the reaction should be gaseous in order to allow their easy removal from the reaction chamber. Further, the byproducts should not react or adsorb on the surface.

Thus, the use of ALD provides the ability to improve the control of thickness, composition, and uniformity of metal containing layers on a substrate. For example, depositing thin layers of metal containing compound in a plurality of cycles provides a more accurate control of ultimate film thickness. This is particularly advantageous when the precursor composition is directed to the substrate and allowed to chemisorb thereon, preferably further including at least one oxygen source gas that reacts with the chemisorbed species on the substrate, and even more preferably wherein this cycle is repeated at least once.

Purging of excess vapor of each reactant following deposition/chemisorption onto a substrate may involve a variety of techniques including, but not limited to, contacting the substrate and/or monolayer with an inert carrier gas and/or lowering pressure to below the deposition pressure to reduce the concentration of a species contacting the substrate and/or chemisorbed species. Examples of carrier gases may include N₂, Ar, He, and the like. Additionally, purging may instead include contacting the substrate and/or monolayer with any substance that allows chemisorption byproducts to desorb and reduces the concentration of a contacting reactant preparatory to introducing another reactant. The contacting reactant may be reduced to some suitable concentration or partial pressure known to those skilled in the art based on the specifications for the product of a particular deposition process.

ALD is often described as a self-limiting process, in that a finite number of sites exist on a substrate to which the first reactant may form chemical bonds. The second reactant might only react with the surface created from the chemisorption of the first reactant and thus, may also be self-limiting. Once all of the finite number of sites on a substrate are bonded with a metal containing precursor, the metal containing precursor will not bond to other of the metal containing precursor species already bonded with the substrate. However, process conditions can be varied in ALD to promote such bonding and render ALD not self-limiting. Accordingly, ALD may also encompass a reactant forming other than one monolayer at a time by stacking of a reactant, forming a layer more than one atom or molecule thick.

During the ALD process, numerous consecutive deposition cycles are conducted in the deposition chamber, each cycle depositing a very thin metal containing layer (usually less than one monolayer such that the growth rate on average is 0.2 to 3.0 Angstroms per cycle), until a layer of the desired thickness is built up on the substrate of interest. The layer deposition is accomplished by alternately introducing (i.e., by pulsing) metal containing precursor composition(s) into the deposition chamber containing a substrate, chemisorbing the metal containing precursor composition(s) as a monolayer onto the substrate surfaces, purging the deposition chamber, then introducing to the chemisorbed precursor composition(s) oxygen source gases. The deposition cycles are repeated until the desired thickness of the metal containing layer is achieved. Preferred thicknesses of the metal containing layers of this invention are at least 1 angstrom, more preferably at least 5 angstroms, and more preferably at least 10 angstroms. Additionally, preferred film thicknesses are typically no greater than 500 angstroms, more preferably no greater than 400 angstroms, and more preferably no greater than 300 angstroms.

Thin metal, e.g., ruthenium, films are attractive for electrode applications in microelectronics. The thickness and resistivity of the film should be minimized. For polycrystalline films, nucleation density determines the minimum thickness that can be achieved. Increasing nucleation density can be beneficial because it results in decreasing the minimum film thickness. Minimizing film thickness minimizes the cost of the film, especially for precious metals such as ruthenium. The film thickness for some applications is also constrained from a technical aspect such as limited space available in a patterned structure.

After deposition of the film on the substrate, the deposited film may be exposed to a plasma treatment. The plasma comprises a reactant processing gas, such as hydrogen, an inert gas, such as argon, and combinations thereof. In the plasma-treatment process, power to generate a plasma is either capacitively or inductively coupled into the chamber to excite the processing gas into a plasma state to produce plasma specie, such as ions, which may react with the deposited material. The plasma is generated by supplying a power density between about 0.6 Watts/cm² and about 3.2 Watts/cm², or between about 200 and about 1000 Watts for a 200 mm substrate, to the processing chamber.

In one embodiment the plasma treatment comprises introducing a gas at a rate between about 5 sccm and about 300 sccm into a processing chamber and generating a plasma by providing power density between about 0.6 Watts/cm² and about 3.2 Watts/cm², or a power at between about 200 Watts and about 1000 Watts for a 200 mm substrate, maintaining the chamber pressure between about 50 milliTorr and about 20 Torr, and maintaining the substrate at a temperature of between about 100° C. and about 600° C. during the plasma process.

It is believed that the plasma treatment lowers the film layer's resistivity, removes contaminants, such as carbon or excess hydrogen, and densifies the film layer to enhance barrier and liner properties. It is believed that species from reactant gases, such as hydrogen species in the plasma react with the carbon impurities to produce volatile hydrocarbons that can easily desorb from the substrate surface and can be purged from the processing zone and processing chamber. Plasma species from inert gases, such as argon, further bombard the layer to remove resistive constituents to lower the layers resistivity and improve electrical conductivity.

It is believed that depositing layers from metal containing precursors and exposing the layers to a post deposition plasma process will produce a layer with improved material properties. The deposition and/or treatment of the materials described herein are believed to have improved diffusion resistance, improved interlayer adhesion, improved thermal stability, and improved interlayer bonding.

In an embodiment of this invention, a method for metallization of a feature on a substrate is provided that comprises depositing a dielectric layer on the substrate, etching a pattern into the substrate, depositing a metal layer on the dielectric layer, and depositing a conductive metal layer on the metal layer. The substrate may be optionally exposed to reactive pre-clean comprising a plasma of hydrogen and argon to remove oxide formations on the substrate prior to deposition of the metal layer. The metal layer can be deposited by ALD processes in the presence of a processing gas, preferably at a pressure less than about 20 Torr. Once deposited, the metal layer can be exposed to a plasma prior to subsequent layer deposition.

A post deposition treatment may also be employed to increase the ratio of metal in the film. Removal of one or more steps in semiconductor manufacture will result in substantial savings to the semiconductor manufacturer.

Metal films are deposited at temperatures lower than 400° C. and form no corrosive byproducts. The metal films are amorphous and are superior barriers to copper diffusion. By tuning the deposition parameters and post deposition treatment, the metal barrier can have a metal rich film deposited on top of it. This metal rich film acts as a wetting layer for copper and may allow for direct copper plating on top of the metal layer. In an embodiment, the deposition parameters may be tuned to provide a layer in which the composition varies across the thickness of the layer. For example, the layer may be metal rich at the silicon portion surface of the microchip, e.g., good barrier properties, and metal rich at the copper layer surface, e.g., good adhesive properties.

The metal containing precursors employed in the ALD processes of this invention may be solid, liquid or gaseous materials, provided that the metal containing precursor is in vapour phase or is evaporated before it is conducted into the reaction chamber and contacted with the substrate surface to bind the precursor onto the substrate. The vapor pressure should be high enough for effective mass transportation. Also, solid and some liquid precursors need to be heated inside the reaction chamber and introduced through heated tubes to the substrates. The necessary vapor pressure should be reached at a temperature below the substrate temperature to avoid the condensation of the precursors on the substrate. Due to the self-limiting growth mechanisms of ALD, relatively low vapor pressure solid precursors may be used though evaporation rates may somewhat vary during the process because of changes in their surface area.

In the ALD methods of this invention, suitable metal containing precursors for depositing conductive metal layers are generally metal compounds where the metal is bound or coordinated to either oxygen or carbon, and more preferably metallocene compounds. Illustrative metals which can be deposited by the ALD methods of this invention include, for example, Re, Ru, Os, Rh, Ir, Pd and Pt. When depositing ruthenium thin films, preferred metal precursors are bis(cyclopentadienyl)ruthenium and tris(2,2,6,6-tetramethyl-3,5-heptanedionato)ruthenium(III) and their derivatives, such as bis(pentamethylcyclopentadienyl)ruthenium and bis(2,2,6,6-tetramethyl-3,5-heptanedionato)(1,5-cyclooctadiene)ruthenium(II).

There are several other characteristics for metal containing precursors used in ALD processes of this invention. The precursors should be thermally stable at the substrate temperature because their decomposition would destroy the surface control and accordingly the advantages of the ALD method that relies on the reaction of the precursor at the substrate surface. A slight decomposition, if slow compared to the ALD growth, may be tolerated.

The metal containing precursors have to chemisorb on or react with the substrate surface, though the interaction between the precursor and the surface as well as the mechanism for the adsorption is different for different precursors. The molecules at the substrate surface should react with the precursor to form the desired monolayer. Additionally, precursors should not react with the layer to cause etching, and precursors should not dissolve in the layer.

Illustrative organometallic compounds useful as metal containing precursors in this invention include, for example, cyclopentadienylpyrrolylruthenium, bis(cyclopentadienyl)ruthenium, methylcyclopentadienylpyrrolylruthenium, bis(methylcyclopentadienyl)ruthenium, ethylcyclopentadienylpyrrolylruthenium, bis(ethylcyclopentadienyl)ruthenium, isopropylcyclopentadienylpyrrolylruthenium, bis(isopropylcyclopentadienyl)ruthenium, tert-butylcyclopentadienylpyrrolylruthenium, bis(tert-butylcyclopentadienyl)ruthenium, methylcyclopentadienyl-2,5-dimethylpyrrolylruthenium, ethylcyclopentadienyl-2,5-dimethylpyrrolylruthenium, isopropylcyclopentadienyl-2,5-dimethylpyrrolylruthenium, tert-butylcyclopentadienyl-2,5-dimethylpyrrolylruthenium, methylcyclopentadienyltetramethylpyrrolylruthenium, ethylcyclopentadienyltetramethylpyrrolylruthenium, isopropylcyclopentadienyltetramethylpyrrolylruthenium, tert-butylcyclopentadienyltetramethylpyrrolylruthenium, 1,2-dimethylcyclopentadienylpyrrolylruthenium, 1,3-dimethylcyclopentadienylpyrrolylruthenium, 1,3-dimethylcyclopentadienyl-2,5-dimethylpyrrolylruthenium, 1,3-dimethylcyclopentadienyltetramethylpyrrolylruthenium, pentadienylpyrrolylruthenium, 2,4-dimethylpentadienylpyrrolylruthenium, 2,4-dimethylpentadienyl-2,5-dimethylpyrrolylruthenium, 2,4-dimethylpentadienyltetramethylpyrrolylruthenium, cyclohexadienylpyrrolylruthenium, cyclohexadienyl-2,5-dimethylpyrrolylruthenium, cyclohexadienyltetramethylpyrrolylruthenium, cycloheptadienylpyrrolylruthenium, cycloheptadienyl-2,5-dimethylpyrrolylruthenium, cycloheptadienyltetramethylpyrrolylruthenium, bis(pyrrolyl)ruthenium, 2,5-dimethylpyrrolylpyrrolylruthenium, tetramethylpyrrolylpyrrolylruthenium, bis(2,5-dimethylpyrrolyl)ruthenium, 2,5-dimethylpyrrolyltetramethylpyrrolylruthenium, and the like.

The organometallic precursors described herein may deposit metal layers depending on the processing gas composition for the ALD process. A metal layer is deposited in the presence of inert processing gases such as argon, a reactant processing gas, such as oxygen, and combinations thereof.

The compound can be employed as a single source precursor or can be used together with one or more other precursors, for instance, with vapor generated by heating at least one other organometallic compound or metal complex. More than one organometallic precursor compound, such as described above, also can be employed in a given process.

The organometallic precursor compound can be used alone or in combination with one or more components, such as, for example, other organometallic precursors, inert carrier gases or reactive gases.

The oxygen source compound can be provided by pulsing oxygen or a mixture of oxygen and another gas into the reaction chamber, or by forming oxygen inside the reactor, by decomposing oxygen containing chemicals, such as H₂O₂, N₂O and/or an organic peroxide. For example, the catalytic formation of an oxygen source compound can be provided by introducing into the reactor a pulse of vaporised aqueous solution of H₂O₂ and conducting the pulse over a catalytic surface inside the reactor and thereafter into the reaction chamber. For instance, the catalytic surface may preferably be a piece of platinum or palladium.

The oxygen source compound is preferably a free-oxygen containing gas pulse, more preferably a molecular oxygen-containing gas pulse and can therefore consist of a mixture of oxygen and inactive gas, for example, nitrogen or argon. Preferred oxygen content of the oxygen-containing gas is from about 10 to 25%. Therefore, one preferred source of oxygen is air.

Before starting the deposition of the film, the substrate is typically heated up to a suitable growth temperature. Preferably, the growth temperature of metal thin film is approximately from about 200 to 500° C., more preferably from about 300 to 360° C.

The processing time depends on the thickness of the layer to be produced and the growth rate of the film. In ALD, the growth rate of a thin film is determined as thickness increases per one cycle as described herein. One cycle consists of the pulsing and purging steps of the precursors and the duration of one cycle is typically between about 0.2 and 30 seconds.

ALD films can be deposited to a desired thickness. For example, films formed can be less than 1 micron thick, preferably less than 500 nanometers and more preferably less than 200 nanometers thick. Films that are less than 50 nanometers thick, for instance, films that have a thickness between about 0.1 and about 20 nanometers, also can be produced.

In general, each step can be as short as the equipment will permit (e.g. milliseconds) and as long as the process requires (e.g. several seconds or minutes). The duration of one cycle can be as short as milliseconds and as long as minutes. The cycle is repeated over a period that can range from a few minutes to hours. Film produced can be a few nanometers thin or thicker, e.g., 1 millimeter (mm).

Generally, in an ALD process each reactant is pulsed sequentially onto a suitable substrate, typically at deposition temperatures of at least 25° C., preferably at least 150° C., and more preferably at least 200° C. The acceptable ALD operating temperature range is the region where the rate of monolayer chemisorption is high compared to the rate of multilayer pyrolysis. For a preferred ALD process, the rate of monolayer chemisorption is as fast as possible and there is no multilayer pyrolysis. Ideally, for each complimentary reactant, the sticking coefficient of the first chemisorbed monolayer is 1, and the sticking coefficient of subsequent contact with the chemisorbed monolayer of the same species is 0. Typical ALD deposition temperatures are no greater than 400° C.

Under such conditions the film growth by ALD is typically self-limiting (i.e., when the reactive sites on a surface are used up in an ALD process, the deposition generally stops), insuring not only excellent conformality but also good large area uniformity plus simple and accurate composition and thickness control. Due to alternate dosing of the precursor composition and reaction gas, detrimental vapor-phase reactions are inherently eliminated.

Pulsing a vaporised metal containing precursor onto the substrate means that the precursor vapour is conducted into the chamber for a limited period of time. Typically, the pulsing time is from about 0.05 to 10 seconds. However, depending on the substrate type and its surface area, the pulsing time may be even higher than 10 seconds.

The pulse duration of precursor composition(s) and inert carrier gas(es) is generally of a duration sufficient to saturate the substrate surface. The pulse duration of reactant gas(es) and inert carrier gas(es) is generally of a duration sufficient to saturate the substrate surface. Typically, the pulse duration is at least 0.1, preferably at least 0.2 seconds, and more preferably at least 0.5 seconds. Preferred pulse durations are generally no greater than 5 seconds, and preferably no greater than 3 seconds.

In the case of relatively small substrates (e.g., up to 4-inch wafers) the mass flow rate of the oxygen-containing gas is preferably between about 1 and 25 sccm, more preferably between about 1 and 8 sccm. In case of larger substrates the mass flow rate of oxygen-containing gas is scaled up. For groupings of individual cycles in ALD processes, the oxygen mass flow rate is different for at least 2 groupings.

Purging the reaction chamber means that gaseous precursors and/or gaseous byproducts formed in the reaction between the precursors are removed from the reaction chamber, such as by evacuating the chamber with a vacuum pump and/or by replacing the gas inside the reactor with an inert gas (purging), such as argon or nitrogen. Typical purging times are from about 0.05 to 20 seconds.

During the ALD process, the substrate temperature may be maintained at a temperature sufficiently low to maintain intact bonds between the chemisorbed precursor composition(s) and the underlying substrate surface and to prevent decomposition of the precursor composition(s). The temperature, on the other hand, should be sufficiently high to avoid condensation of the precursor composition(s). Typically the substrate is kept at a temperature of at least 25° C., preferably at least 150° C., and more preferably at least 200° C. Typically the substrate is kept at a temperature of no greater than 400° C. Thus, the first reactant or precursor composition is chemisorbed at this temperature. Surface reaction of the gaseous oxygen source compound can occur at substantially the same temperature as chemisorption of the metal containing precursor or, optionally but less preferably, at a substantially different temperature. Clearly, some small variation in temperature, as judged by those of ordinary skill, can occur but still be considered substantially the same temperature by providing a reaction rate statistically the same as would occur at the temperature of the metal containing precursor chemisorption. Alternatively, chemisorption and subsequent reactions could instead occur at substantially exactly the same temperature.

For a typical ALD deposition process, the pressure inside the deposition chamber is at least 10⁻⁸ torr (1.3.times.10⁻⁶ Pa), preferably at least 10⁻⁷ torr (1.3.times.10⁻⁵ Pa), and more preferably at least 10⁻⁶ torr (1.3.times.10⁻⁴ Pa). Further, deposition pressures are typically no greater than 1000 torr (1.3.times.10⁵ Pa), preferably no greater than 10 torr (1.3.times.10³ Pa), and more preferably no greater than 10⁻¹ torr (13 Pa). Typically, the deposition chamber is purged with an inert carrier gas after the vaporized precursor composition(s) have been introduced into the chamber and/or reacted for each cycle. The inert carrier gas/gases can also be introduced with the vaporized precursor composition(s) during each cycle.

Examples of substrates that can be coated employing the method of the invention include solid substrates such as metal substrates, e.g., Al, Ni, Ti, Co, Pt, metal silicides, e.g., TiSi₂, CoSi₂, NiSi₂; semiconductor materials, e.g., Si, SiGe, GaAs, InP, diamond, GaN, SiC; insulators, e.g., SiO₂, Si₃N₄, HfO₂, Ta₂O₅, Al₂O₃, barium strontium titanate (BST); or on substrates that include combinations of materials. In addition, films or coatings can be formed on glass, ceramics, plastics, thermoset polymeric materials, and on other coatings or film layers. In preferred embodiments, film deposition is on a substrate used in the manufacture or processing of electronic components. In other embodiments, a substrate is employed to support a low resistivity conductor deposit that is stable in the presence of an oxidizer at high temperature or an optically transmitting film.

Examples of suitable arrangements of reactors used for the deposition of thin films according to the processes of this invention are commercially available ALD equipment. Atomic layer deposition of thin metal films may be processed in an ALD system under computer control to perform various embodiments, and operated under computer-executable instructions to perform those embodiments. In an embodiment, a computerized method and the computer-executable instructions for a method for forming a thin metal film includes forming the metal containing film by ALD, where the metal containing precursor and oxygen source compound are pulsed into a reaction chamber for a predetermined periods. The predetermined periods are controlled for the metal containing precursor and oxygen source compound pulsed into the reaction chamber. Further, the substrate may be maintained at a selected temperature for each pulsing of a precursor and oxygen source compound, where the selected temperature is set independently for pulsing the precursor and oxygen source compound. In addition, each pulsing of a precursor and oxygen source compound is followed by purging the reaction chamber with a purging gas.

The computerized method and the computer-executable instructions for a method for forming a thin metal film include controlling the environment of the reaction chamber. Additionally, the computerized method controls the pulsing of purging gases, one each for the precursor gas and oxygen source compound and pulsing each purging gas after pulsing the associated precursor gas and oxygen source compound. Using a computer to control parameters for growing the metal film provides for processing the metal film over a wide range of parameters allowing for the determination of an optimum parameter set for the ALD system used. The computer-executable instructions may be provided in any computer-readable medium.

In producing films by the ALD methods of the invention, raw materials can be directed to a gas-blending manifold to produce process gas that is supplied to a deposition reactor, where film growth is conducted. Raw materials include, but are not limited to, carrier gases, oxygen source gases, purge gases, metal containing precursors, etch/clean gases, and others. Precise control of the process gas composition is accomplished using mass-flow controllers, valves, pressure transducers, and other means, as known in the art. An exhaust manifold can convey gas exiting the deposition reactor, as well as a bypass stream, to a vacuum pump. An abatement system, downstream of the vacuum pump, can be used to remove any hazardous materials from the exhaust gas. The deposition system can be equipped with in-situ analysis system, including a residual gas analyzer, which permits measurement of the process gas composition. A control and data acquisition system can monitor the various process parameters (e.g., temperature, pressure, flow rate, etc.).

This invention in part provides a method of processing a substrate to form a metal-based material layer, e.g., ruthenium layer, on the substrate by ALD. In particular, this invention relates in part to a method for processing a substrate in a processing chamber by an ALD process comprising a plurality of individual cycles. The plurality of individual cycles comprise at least two groupings of individual cycles. The individual cycles comprise (i) introducing a gaseous metal containing precursor into the reaction chamber and exposing the substrate to the gaseous metal containing precursor, wherein at least a portion of the metal containing precursor is chemisorbed onto the surface of the substrate to form a monolayer thereon, (ii) stopping introduction of the metal containing precursor and purging the volume of the reaction chamber, (iii) introducing a gaseous oxygen source compound into the reaction chamber and exposing the monolayer to the gaseous oxygen source compound, wherein at least a portion of the oxygen source compound chemically reacts with the monolayer, and (iv) stopping introduction of the oxygen source compound and purging the volume of the reaction chamber. The method involves repeating the individual cycles until a thin film of desired thickness is obtained. The method also involves carrying out at least two groupings of individual cycles at different process conditions.

This invention includes a method for forming a metal containing material on a substrate, e.g., a microelectronic device structure, by ALD. In particular, this invention relates in part to a method for forming a metal containing material on a substrate in a reaction chamber by an ALD process comprising a plurality of individual cycles, said plurality of individual cycles comprising at least two groupings of individual cycles, wherein said individual cycles comprise (i) introducing a gaseous metal containing precursor into said reaction chamber containing a substrate and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber; (iii) introducing a gaseous oxygen source compound into said reaction chamber and exposing said monolayer to said gaseous oxygen source compound, wherein at least a portion of said oxygen source compound chemically reacts with said monolayer; and (iv) stopping introduction of said oxygen source compound and purging the volume of said reaction chamber; repeating said individual cycles until a thin film of desired thickness is obtained; and carrying out at least two groupings of individual cycles at different process conditions. The metal containing material on the substrate can thereafter be metallized with copper or integrated with a ferroelectric thin film (e.g., SrTiO3).

In an embodiment of this invention, a method is provided for fabricating a microelectronic device structure by ALD. In particular, this invention relates in part to a method of fabricating a microelectronic device structure in a reaction chamber by an ALD process comprising a plurality of individual cycles. The plurality of individual cycles comprise at least two groupings of individual cycles. The individual cycles comprise (i) introducing a gaseous metal containing precursor into the reaction chamber containing a substrate and exposing the substrate to the gaseous metal containing precursor, wherein at least a portion of the metal containing precursor is chemisorbed onto the surface of the substrate to form a monolayer thereon, (ii) stopping introduction of the metal containing precursor and purging the volume of the reaction chamber, (iii) introducing a gaseous oxygen source compound into the reaction chamber and exposing the monolayer to the gaseous oxygen source compound, wherein at least a portion of the oxygen source compound chemically reacts with the monolayer, and (iv) stopping introduction of the oxygen source compound and purging the volume of the reaction chamber. The method involves repeating the individual cycles until a thin film of desired thickness is obtained. The method also involves carrying out at least two groupings of individual cycles at different process conditions. The method further comprises incorporating the thin film into a semiconductor integration scheme.

The metal containing precursor compounds can be employed to produce films that include a single metal or a film that includes a single metal. Mixed films also can be deposited, for instance mixed metal films. Such films are produced, for example, by employing more than one organometallic precursor.

According to another embodiment of this invention, the final thin film may consist of two or more different metal layers on top of each other. For example, the growth can be started with the deposition of ruthenium and ended with the deposition of another suitable metal.

Films formed by the methods described herein can be characterized by techniques known in the art, for instance, by X-ray diffraction, Auger spectroscopy, X-ray photoelectron emission spectroscopy, atomic force microscopy, scanning electron microscopy, and other techniques known in the art. Resistivity and thermal stability of the films also can be measured, by methods known in the art.

The method of this invention can be conducted to deposit a film on a substrate that has a smooth, flat surface. In an embodiment, the method is conducted to deposit a film on a substrate used in wafer manufacturing or processing. For instance, the method can be conducted to deposit a film on patterned substrates that include features such as trenches, holes or vias. Furthermore, the method of the invention also can be integrated with other steps in wafer manufacturing or processing, e.g., masking, etching and others. Additionally, these embodiments for ALD processing of metal films may be implemented to form transistors, capacitors, memory devices, and other electronic systems.

Various modifications and variations of this invention will be obvious to a worker skilled in the art and it is to be understood that such modifications and variations are to be included within the purview of this application and the spirit and scope of the claims.

### EXAMPLE 1

Ruthenium containing films were deposited using a thin film deposition system described by Atwood et al., ECS Proceedings Volume 2003-08, 2003, 847. The films were deposited on a 3 inch silicon wafer, with a 250 nanometer (nm) layer of silicon dioxide. The ALD cycle consisted of four repeating steps. The substrates were exposed to the following materials during each step: step 1 was a mixture of (ethylcyclopentadienyl)(pyrrolyl)ruthenium (ECPR) precursor and argon, step 2 was 100% argon purge, step 3 was a mixture of oxygen and argon, and step 4 was 100% argon purge. During step 1 the precursor chemically adsorbed to the surface in a self-limiting fashion (i.e., surface coverage limited to a monolayer or less). Step 2 was used to purge the vapor phase of any unreacted precursor. During step 3, the chemisorbed monolayer of precursor reacted with oxygen. The products of step 3 were monitored by a mass spectrometer, and determined to include H₂O, CO and CO2. The relative concentration of the aforementioned products depended on the process conditions. Step 4 was used to purge the vapor phase of any remaining O₂, in preparation for step 1 of the next cycle. Unless otherwise specified, the duration for steps 1 and 3 was 10 seconds. Unless otherwise specified, the duration for steps 2 and 4 (argon purge) was 20 seconds. Therefore, the total duration of one 4 step cycle was typically 60 seconds (1 minute).

The reactor was operated at a pressure of 5 Torr. The temperature of the substrate was generally between 290 and 340° C. The precursor used was 99+% ECPR. The estimated vapor pressure of ECPR was 0.3 Torr at 90° C. The ECPR was vaporized using 100 sccm of argon at 50 Torr and 90° C. Assuming the percent saturation of ECPR exiting the vaporizer was 50%, this resulted in a precursor vaporization rate of 0.3 sccm or 3.5 mg/min.

Several experiments were conducted using a fixed concentration of oxygen in step 3, throughout deposition of the entire ruthenium layer. The results showed that 300 ALD cycles using ECPR with low concentration of oxygen (10 sccm O₂ and 640 sccm Ar) during step 3 resulted in a smooth 50 nm film, but the film exhibited blistering. In contrast, 300 ALD cycles using ECPR with high concentration of oxygen (200 sccm O₂ and 450 sccm Ar) during step 3 resulted in a rough deposit of discrete nuclei about 50 nm in size, which were incapable of blistering. Experiments were also conducted using 20 and 40 sccm of O₂ during step 3. These results showed that decreasing the oxygen concentration during step 3 of the ALD process resulted in increased nucleation density (i.e., smoother films) and increased blistering.

A 2 step process was developed that combined two of the aforementioned processes at fixed conditions and resulted in a film that was similar in thickness (˜55 nm), but exhibited very little blistering compared to operating at fixed conditions with low oxygen concentration. This process started with 50 ALD cycles at low oxygen conditions during step 3, followed by 250 ALD cycles at high oxygen conditions during step 3. A refined process using 10 ALD cycles at low oxygen during step 3, followed by 190 ALD cycles at high oxygen during step 3 produced a 30 nm film with no detectable blisters and excellent adhesion. These results confirm that multi-step processes (i.e., processes with 2 or more steps) operated at different oxygen concentration during step 3 can be used to produce thin ruthenium films, that are blister-free.

1. A method of forming a thin film on a substrate in a reaction chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber; (iii) introducing a gaseous oxygen source compound into said reaction chamber and exposing said monolayer to said gaseous oxygen source compound, wherein at least a portion of said oxygen source compound chemically reacts with said monolayer; and (iv) stopping introduction of said oxygen source compound and purging the volume of said reaction chamber; repeating said individual cycles until a thin film of desired thickness is obtained; and carrying out at least two groupings of individual cycles at different process conditions.

2. The method of claim 1 wherein, for at least one grouping of individual cycles, the concentration of said gaseous oxygen source compound is different from at least one other grouping of individual cycles.

3. The method of claim 1 wherein, for at least one grouping of individual cycles, the temperature is different from at least one other grouping of individual cycles.

4. The method of claim 1 wherein, for at least one grouping of individual cycles, the pressure is different from at least one other grouping of individual cycles.

5. The method of claim 1 wherein said groupings of individual cycles have from about 1 to about 1000 individual cycles each.

6. The method of claim 1 wherein the number of individual cycles included in said groupings of individual cycles can be the same or different.

7. The method of claim 1 wherein said oxygen source compound comprises molecular oxygen or free oxygen.

8. The method of claim 1 wherein said gaseous metal containing precursor is selected from a Re, Ru, Os, Rh, Ir, Pd and Pt containing precursor.

9. The method of claim 1 wherein said thin film has a thickness of less than about 50 nm.

10. The method of claim 1 wherein said substrate is comprised of a material selected from the group consisting of a metal, a metal silicide, a semiconductor, an insulator and a barrier material.

11. The method of claim 1 wherein said substrate is a patterned wafer.

12. A method for processing a substrate in a processing chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber; (iii) introducing a gaseous oxygen source compound into said reaction chamber and exposing said monolayer to said gaseous oxygen source compound, wherein at least a portion of said oxygen source compound chemically reacts with said monolayer; and (iv) stopping introduction of said oxygen source compound and purging the volume of said reaction chamber; repeating said individual cycles until a thin film of desired thickness is obtained; and carrying out at least two groupings of individual cycles at different process conditions.

13. The method of claim 12 furthering comprising depositing a metal layer on the thin film.

14. The method of claim 12 wherein the metal layer comprises copper and is deposited by an electroplating technique.

15. A method for forming a metal containing material on a substrate in a reaction chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber containing a substrate and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber; (iii) introducing a gaseous oxygen source compound into said reaction chamber and exposing said monolayer to said gaseous oxygen source compound, wherein at least a portion of said oxygen source compound chemically reacts with said monolayer; and (iv) stopping introduction of said oxygen source compound and purging the volume of said reaction chamber; repeating said individual cycles until a thin film of desired thickness is obtained; and carrying out at least two groupings of individual cycles at different process conditions.

16. The method of claim 15 wherein said metal containing material on said substrate is thereafter metallized with copper or integrated with a ferroelectric thin film.

17. The method of claim 15 wherein the substrate comprises a microelectronic device structure.

18. A method of fabricating a microelectronic device structure in a reaction chamber by an atomic layer deposition process comprising a plurality of individual cycles, said plurality of individual cycles comprising at least two groupings of individual cycles, wherein said individual cycles comprise (i) introducing a gaseous metal containing precursor into said reaction chamber containing a substrate and exposing said substrate to said gaseous metal containing precursor, wherein at least a portion of said metal containing precursor is chemisorbed onto the surface of said substrate to form a monolayer thereon, (ii) stopping introduction of said metal containing precursor and purging the volume of said reaction chamber; (iii) introducing a gaseous oxygen source compound into said reaction chamber and exposing said monolayer to said gaseous oxygen source compound, wherein at least a portion of said oxygen source compound chemically reacts with said monolayer; and (iv) stopping introduction of said oxygen source compound and purging the volume of said reaction chamber; repeating said individual cycles until a thin film of desired thickness is obtained; and carrying out at least two groupings of individual cycles at different process conditions.

19. The method of claim 18 further comprising incorporating the thin film into a semiconductor integration scheme.

20. The method of claim 18 wherein said thin film on said substrate is thereafter metallized with copper or integrated with a ferroelectric thin film.
